(19) United States
(12) Patent Application Publication
(10) Pub. No.: US 2015/0287799 A1
(43) Pub. Date: Oct. 8, 2015

(54) SEMICONDUCTOR DEVICE, DISPLAY PANEL, AND SEMICONDUCTOR DEVICE MANUFACTURING METHOD

(71) Applicant: SHARP KABUSHIKI KAISHA, Osaka-shi, Osaka (JP)

(72) Inventors: Shogo Murashige, Osaka (JP); Takeshi Hara, Osaka (JP); Hirohiko Nishiki, Osaka (JP); Izumi Ishida, Osaka (JP)

(73) Assignee: Sharp Kabushiki Kaisha, Osaka (JP)

(21) Appl. No.: 14/430,424

(22) PCT Filed: Sep. 18, 2013
(86) PCT No.: PCT/JP2013/075074

§ 371 Date: Mar. 23, 2015

(30) Foreign Application Priority Data
Sep. 26, 2012 (JP) 2012-212609

(51) Int. Cl. H01L 29/45; G02F 1/1335; H01L 29/66; G02F 1/1368; H01L 29/786; H01L 27/12

(52) U.S. Cl. CPC H01L 29/45; H01L 29/7869; H01L 27/124; H01L 29/66969; H01L 27/127; G02F 1/1368; G02F 1/133514

(57) ABSTRACT

The present invention suppresses electrochemical corrosion in a TFT between an oxide conductor and a source/drain wiring line containing aluminum. In this semiconductor device, a gate layer containing a gate line and a gate electrode is formed on a substrate, and a semiconductor layer made of an oxide semiconductor is formed so as to overlap the gate electrode of the gate layer, with a gate insulating film therebetween. A source electrode and a drain electrode are formed by spacing apart a source wiring layer on the semiconductor layer. The source wiring layer is configured by laminating first conductive layers made of Al and a second conductive layer constituted by a metal film made of a metal other than an amphoteric metal. The drain electrode and a pixel electrode are electrically connected to each other via a contact hole in protective layers formed on the source wiring layer.

### TECHNICAL FIELD

The present invention relates to: a semiconductor device having thin film transistors (TFTs) with an oxide semiconductor; a display panel; and a method of manufacturing the semiconductor device.

### BACKGROUND ART

Recent years have seen progress in the development of technologies applying oxide semiconductors to TFTs used for displays and the like. Japanese Patent Application Laid-Open Publication No. 2007-123861 discloses a semiconductor device having a TFT that employs an oxide semiconductor. In the semiconductor device described in Japanese Patent Application Laid-Open Publication No. 2007-123861, a multilayer wiring line formed by laminating aluminum and titanium is used as a source/drain wiring line. In this multilayer wiring line, titanium and aluminum are laminated in that order from the oxide semiconductor.

### SUMMARY OF THE INVENTION

Incidentally, a source/drain wiring line is formed by etching through photolithography a conductive film deposited on a gate insulating film for the source/drain wiring line and stripping the resist on the conductive film. An alkaline stripping solution is used to strip the resist, and, during the step of stripping the resist, the conductive film of the source/drain wiring line and the oxide semiconductor are exposed to the stripping solution. When the source/drain wiring line and the oxide semiconductor are exposed to the stripping solution, the aluminum in the source/drain wiring line dissolves. Electrochemical corrosion occurs between the source/drain wiring line and the oxide semiconductor, degrading the film quality of the oxide semiconductor.

The purpose of the present invention is to provide a technology for suppressing electrochemical corrosion in a TFT between the oxide semiconductor and the source/drain wiring line containing aluminum.

A semiconductor device provided by the present invention includes: a gate electrode formed on a substrate; a gate insulating film covering the gate electrode; a semiconductor layer made of an oxide semiconductor formed so as to overlap the gate electrode, with the gate insulating film therebetween; a source wiring layer formed on the gate insulating film by spacing apart a conductive film above the semiconductor layer, the conductive film constituted by a first conductive layer made of aluminum provided on a side of the semiconductor layer and a second conductive layer laminated onto the first conductive layer; and a pixel electrode electrically connected to the source wiring layer via a contact hole provided in an insulation layer formed in a layer above the source wiring layer, wherein the second conductive layer is constituted by a metal film made of a metal other than an amphoteric metal.

According to the configurations of the present invention, it is possible to suppress electrochemical corrosion in a TFT between the oxide semiconductor and the source/drain electrode containing aluminum.

### BRIEF DESCRIPTION OF THE DRAWINGS

FIG. 1 is a diagram showing a schematic configuration of a display panel according to the embodiment.

FIG. 2 is a diagram showing a schematic configuration of an active matrix substrate in the embodiment.

FIG. 3 shows a schematic configuration of an enlarged portion of the active matrix substrate shown in FIG. 2.

FIG. 4 is a cross-sectional view of FIG. 3 along the line A-A′.

FIG. 5A is a diagram showing a step of manufacturing a semiconductor device according to the embodiment.

FIG. 5B is a diagram showing a step of manufacturing the semiconductor device according to the embodiment.

FIG. 5C is a diagram showing a step of manufacturing the semiconductor device according to the embodiment.

FIG. 5D is a diagram showing a step of manufacturing the semiconductor device according to the embodiment.

FIG. 5E is a diagram showing a step of manufacturing the semiconductor device according to the embodiment.

FIG. 6 is a cross-sectional view of a semiconductor device according to Modification Example 1.

FIG. 7A is a diagram showing a step of manufacturing the semiconductor device according to Modification Example 1.

FIG. 7B is a diagram showing a step of manufacturing the semiconductor device according to Modification Example 1.

FIG. 7C is a diagram showing a step of manufacturing the semiconductor device according to Modification Example 1.

### DETAILED DESCRIPTION OF EMBODIMENTS

A semiconductor device provided by an embodiment of the present invention includes: a gate electrode formed on a substrate; a gate insulating film covering the gate electrode; a semiconductor layer made of an oxide semiconductor formed so as to overlap the gate electrode, the gate insulating film being interposed therebetween; a source wiring layer formed on the gate insulating film by spacing apart a conductive film on the semiconductor layer, the conductive film of the source wiring layer including a first conductive layer made of aluminum provided on a side of the semiconductor layer and a second conductive layer stacked on the first conductive layer; and a pixel electrode electrically connected to the source wiring layer via a contact hole provided in an insulating layer formed in a layer above the source wiring layer, wherein the second conductive layer of the source wiring layer is a metal film made of a metal other than an amphoteric metal (first configuration). According to the first configuration, in the source wiring layer, the second conductive layer is formed on the first conductive layer made of aluminum. Additionally, for the second conductive layer, a conductive film less susceptible than aluminum to electrochemical corrosion between the source wiring layer and the oxide semiconductor is used. For this reason, aluminum is less easily exposed to the alkaline stripping solution when the resist is stripped to form source/drain electrodes, and it is possible to suppress galvanic corrosion between the oxide semiconductor and the source wiring layer.

In the second configuration, the first conductive layer of the source wiring layer may include a first conductive film and a second conductive film stacked together, and the first conductive film may be an aluminum metal film in contact with the second conductive layer of the source wiring layer, and the second conductive film may be a metal film made of titanium or a metal compound including titanium that is in contact with the semiconductor layer. According to the second configuration, the aluminum conductive film is formed between the titanium-based conductive film, which is in contact with the oxide semiconductor, and the second conductive layer. For this reason, even if the source wiring layer is exposed to the alkaline stripping solution during the step of stripping the resist, galvanic corrosion occurs less easily between the aluminum and the oxide semiconductor, making it possible to prevent the film quality of the oxide semiconductor from degrading.

In the third configuration, the second conductive layer of the source wiring layer may be a metal film made of a metal compound including molybdenum.

In the fourth configuration, the second conductive layer of the source wiring layer may be a metal film made of a metal compound including titanium.

In the fifth configuration, the oxide semiconductor may include indium, gallium, zinc, and oxygen.

A display panel according to one embodiment of the present invention includes an active matrix substrate having the semiconductor device according to any one of the first to fifth configurations; a opposite substrate having a common electrode and color filters; and a liquid crystal layer sandwiched between the active matrix substrate and the opposite substrate.

A display panel according to one embodiment of the present invention includes an active matrix substrate having the semiconductor device according to any one of the first to fifth configurations and a common electrode; an opposite substrate having color filters; and a liquid crystal layer sandwiched between the active matrix substrate and the opposite substrate.

A method of manufacturing a semiconductor device according to one embodiment of the present invention is a method of manufacturing a semiconductor device equipped with thin film transistors, including (A) forming a gate layer having a gate line and a gate electrode; (B) forming a gate insulating film so as to cover the gate layer; (C) forming a semiconductor layer made of an oxide semiconductor so as to overlap the gate electrode, the gate insulating film being interposed therebetween; (D) forming a source electrode and a drain electrode by forming: a first conductive layer made of aluminum on the gate insulating film and on the semiconductor layer; and by forming, on the first conductive layer, a conductive film including a first conductive layer made of aluminum on a side of the semiconductor layer and a second conductive layer stacked on the first conductive layer, a gap being present therein on the semiconductor layer; (E) forming a first protective layer covering the source wiring layer and a second protective layer covering the first protective layer; (F) forming a contact hole that exposes the drain electrode by etching the first protective layer and the second protective layer; and (G) forming a pixel electrode so as to contact the drain connective film in the contact hole, wherein the second conductive layer is a metal film made of a metal other than an amphoteric metal.

An embodiment of the present invention will be described below with reference to diagrams. Identical reference characters will be applied to identical or equivalent portions in diagrams, and descriptions thereof will not be repeated.

### EMBODIMENTS

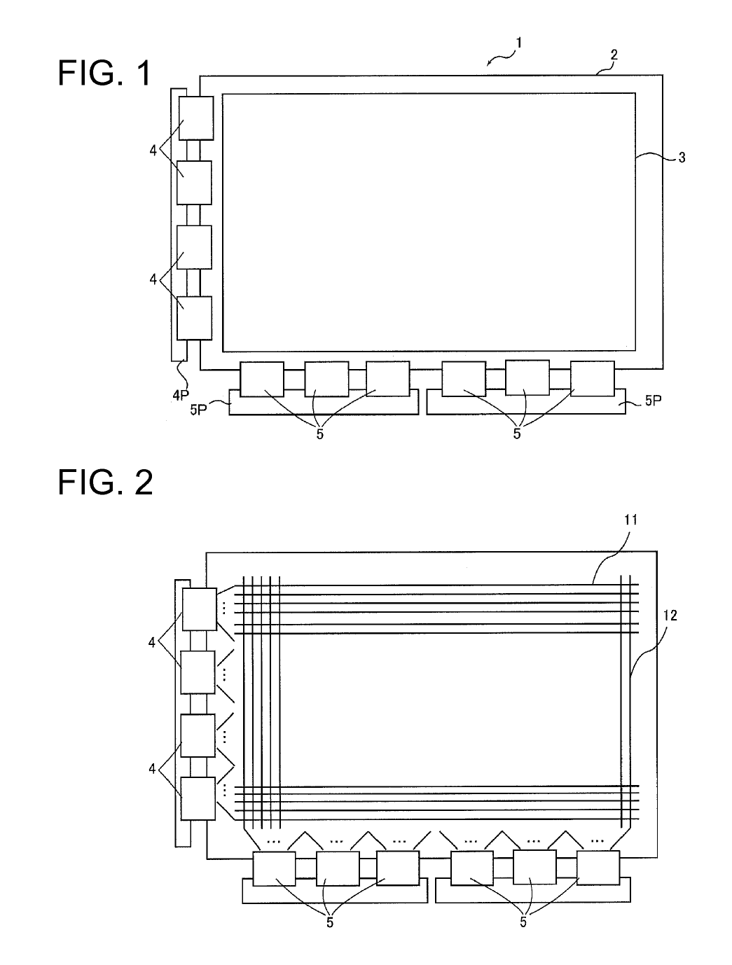

FIG. 1 is a diagram showing a schematic configuration of the display panel of a liquid crystal display device that has the semiconductor device according to the present embodiment. A display panel 1 has an active matrix substrate 2, an opposite substrate 3, and a liquid crystal layer (omitted from the diagram) sandwiched between these substrates. On the opposite substrate 3 shown in FIG. 1, a common electrode (omitted from the diagram) and a color filter (omitted from diagram) are formed. The display panel 1 is illuminated with light from a backlight (omitted from the diagram) provided on the reverse side of the active matrix substrate 2.

As shown in FIG. 1, gate drivers 4 and source drivers 5 are provided on the active matrix substrate 2. The gate drivers 4 and the source drivers 5 are configured by TAB (Tape Automated Bonding) or the like, by which each semiconductor chip of the gate drivers 4 and the source drivers 5 is mounted on a film such as a polyimide film. Each of the gate drivers 4 and the source drivers 5 is electrically connected to the active matrix substrate 2 and is also electrically connected to printed boards 4P and 5P. The gate drivers 4 and source drivers 5 receive externally inputted signals such as timing signals and image signals from a control circuit (omitted from the diagram) via the printed boards 4P and 5P, to which each of the gate drivers 4 and the source drivers 5 is connected. The display panel 1 drives liquid crystal within the liquid crystal layer based on the data signals and the scan signals outputted by the source drivers 4 and the gate drivers 5 in accordance with the externally inputted signals, and displays images in a display region.

FIG. 2 is a diagram showing a schematic configuration of the active matrix substrate 2. Formed on the active matrix substrate 2 are a gate line group 11, which is connected to each gate driver 4, and a source line group 12, which is connected to each source driver 5. Gate lines 11 are formed in a parallel manner along one direction of a substrate 20. Source lines 12 intersect the gate lines 11 and are formed in a parallel manner. A region surrounded by each gate line 11 and each source line 12 forms one pixel, and a pixel area made up of all pixels constitutes the display region of the display panel 1. While omitted from FIG. 2, a terminal group that is electrically connected to the gate drivers 4 and that inputs gate signals to the gate drivers 4 is formed outside the display region. Further, a terminal group that is electrically connected to the source drivers 5 and that inputs source signals to the source drivers 5 is formed outside the display region.

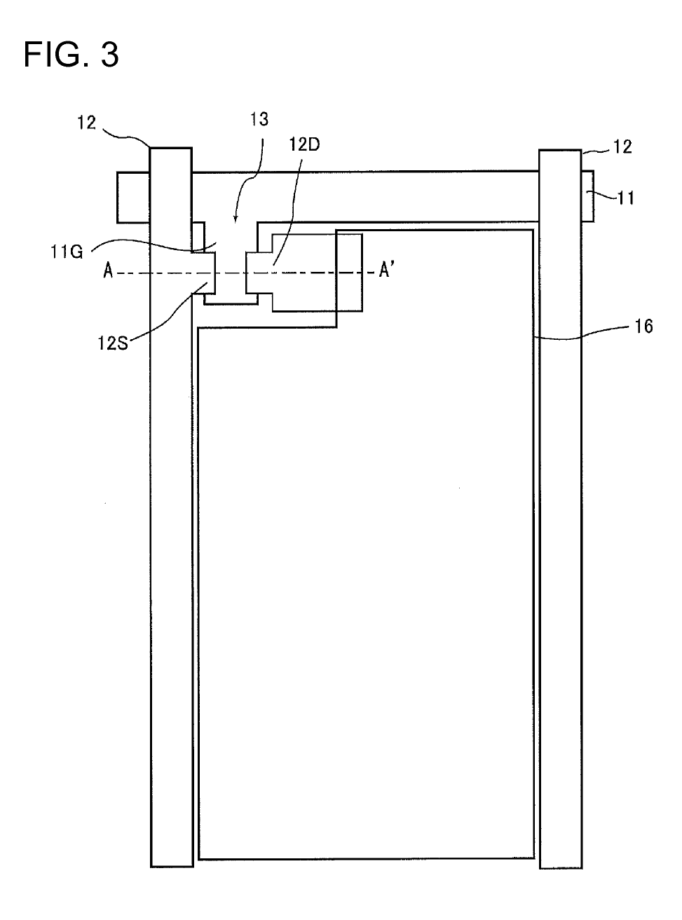

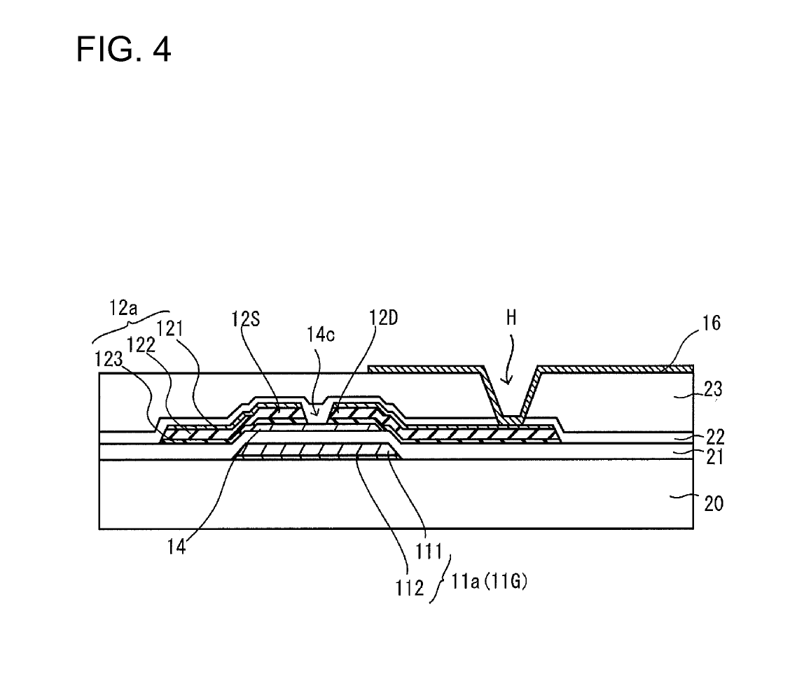

Now, a portion of one pixel will be described using FIGS. 3 and 4. FIG. 3 is a plan view of an enlarged portion of one pixel. As shown in FIG. 3, a TFT 13 is formed in each pixel in the vicinity of an intersection of the source line 12 and the gate line 11. Additionally, a pixel electrode 16, which is electrically connected to the TFT 13, is formed for each pixel. The TFT 13 has a gate electrode 11G, a source electrode 12S, a drain electrode 12D, and a semiconductor portion 14 (see FIG. 4). The pixel electrode 16 is electrically connected to the drain electrode 12D of the TFT 13.

FIG. 4 is a cross-sectional view of the line A-A′ in FIG. 3. As shown in FIG. 4, a gate layer 11a is formed on top of the substrate 20 made of a glass or the like having a transparent property and an insulating property. A formation of the gate layer 11a results in a formation of the gate line 11 and the gate electrode 11G. The gate layer 11a is made of a metal such as copper (Cu), aluminum (Al), titanium (Ti), molybdenum (Mo), or an alloy thereof or the like, for example. In the present embodiment, the gate layer 11a is constituted by a multilayer film with a Cu upper layer 111 and a Ti lower layer 112.

Formed above the gate layer 11a (gate electrode 11G) is a semiconductor portion 14 made of an oxide semiconductor, with a gate insulating film 21 therebetween. In the present embodiment, the gate insulating film 21 is constituted by a single layer film such as a silicon nitride (SiN_{g}) film, a silicon oxide (SiO₂) film, or the like. The semiconductor portion 14 is constituted by indium (In), gallium (Ga), zinc (Zn), and oxygen (O).

Above the gate insulating film 21 and the semiconductor portion 14, a source wiring layer 12a is formed so as to be spaced apart above the semiconductor portion 14. As a result, a channel region 14c, the source electrode 12S, and the drain electrode 12D are formed.

In the present embodiment, the source wiring layer 12a is constituted by the three layers of a first layer 121, a second layer 122, and a third layer 123, in that order from the top layer side. In the present embodiment, the first layer 121 is constituted by molybdenum nitride (MoN), the second layer 121 by Al, and the third layer 122 by Ti. The first layer 121 is an example of a second conductive layer, and the second layer 122 and the third layer 123 are an example of a first conductive layer.

After the source wiring layer 12a is deposited, the first layer 121, or the uppermost layer of the source wiring layer 12a, is exposed to a resist stripping solution used to form the source electrode 12S and the drain electrode 12D. For this reason, the first layer 121 is constituted by a metal film that suppresses galvanic corrosion between the first layer 121 and the oxide semiconductor, or a metal film made of a metal other than an amphoteric metal, which is dissolved by an alkaline solution. Here, other than the MoN mentioned above, Mo, Ti, MoNb (molybdenum niobium), or W (tungsten), or a nitride of any one of these metals may be used as the first layer 121.

In this manner, forming an MoN conductive layer on top of an Al conductive layer makes Al less easily exposed to the stripping solution during the step of stripping the resist, in comparison to a source wiring line of a two-layered structure constituted by Al and Ti. Additionally, since a metal film that is less soluble to an alkaline solution is formed in a layer above Al, galvanic corrosion between the semiconductor portion 14 and the source wiring layer 12a is suppressed even if the source wiring layer 12a is exposed to the stripping solution.

A protective layer 22 and a protective layer 23 are formed in layers over the substrate 20, where the source wiring layer 12a was formed, so as to cover the source wiring layer 12a. In the protective layer 22 and the protective layer 23, a contact hole H is formed above the drain electrode 12D. In the contact hole H, the pixel electrode 16 is formed so as to cover a portion of the protective layer 23. The pixel electrode 16 is electrically connected to the drain electrode 12D via the contact hole H. The protective layer 22 is constituted by an inorganic insulation film such as SiO₂ while the protective layer 23 is constituted by an organic insulation film such as a positive-type photosensitive resin film. The pixel electrode 16 is constituted by a transparent conductive film such as ITO. The protective layer 22 is an example of a first protective layer and the protective layer 23 is an example of a second protective layer.

(Method of Manufacturing)

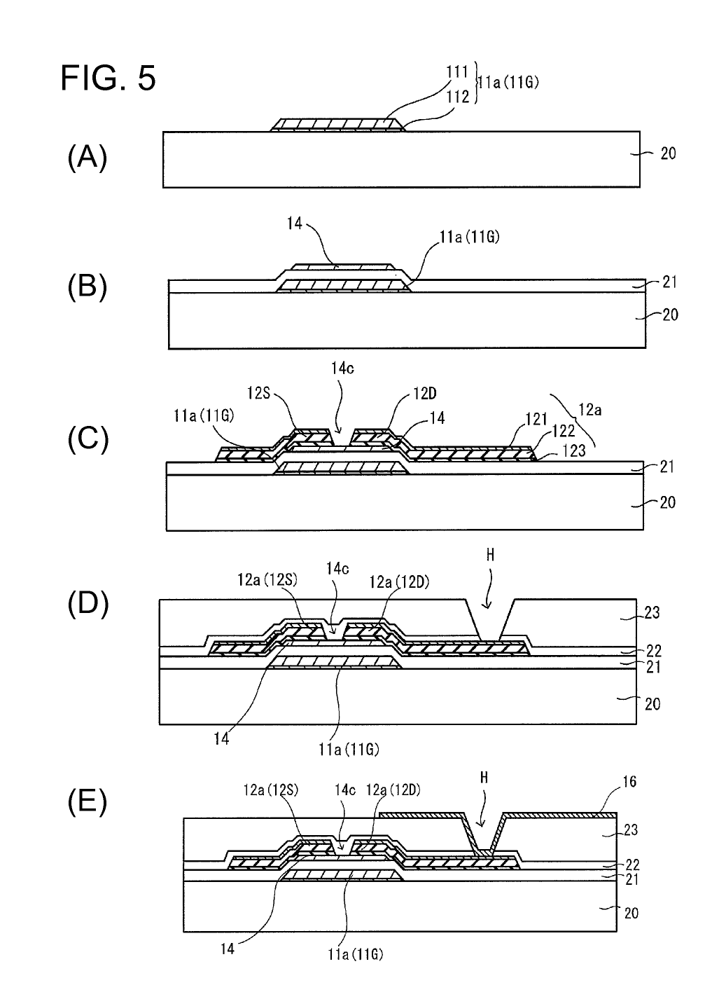

Next, an example of a method of manufacturing the semiconductor device according to the present embodiment will be explained. FIGS. 5A to 5E are cross-sectional views showing the steps of manufacturing the semiconductor device shown in FIG. 4.

(1) Forming the Gate Layer 11a

As shown in FIG. 5A, a conductive film for the gate layer 11a is deposited on the substrate 20 using a sputtering method. Then, using photolithography, a resist mask is formed and a resist pattern is created in a region where the TFT 13 will be formed. Subsequently, patterning is performed by removing portions of the conductive film not covered by the resist mask by wet etching and stripping the resist. In this way, the gate electrode 11G and the gate line 11 are formed as an integral whole. In the present embodiment, a multilayer film with the upper layer 111 made of Cu and the lower layer 112 made of Ti is used as the gate layer 11a. Using Ti for the lower layer 112 improves adhesion to the substrate 20. The film thickness of the upper layer 111 is between 200 nm and 500 nm, for example, and the film thickness of the lower layer 112 is between 30 nm and 100 nm, for example. For the gate layer 11a, it is possible to use a single layer film containing: a metal such as Cu, Al, Ti, Mo, or the like; an alloy thereof; or a nitride thereof.

(2) Forming the Gate Insulating Film 21

Next, as shown in FIG. 5B, a gate insulating film 21 is deposited using a plasma CVD method over the substrate 20, where the gate layer 11a was formed. A single layer film of SiNₓ is used for the gate insulating film 21. The film thickness of the gate insulating film 21 is between 200 nm and 500 nm, for example. A multilayer film formed by laminating SiNₓ and SiO₂ or a single layer film of SiO₂ may also be used for the gate insulating film 21.

(3) Forming the Semiconductor Portion 14

Using a sputtering method, an oxide semiconductor is deposited as a semiconductor layer over the substrate 20, where the gate insulating film 21 was formed. Then, using photolithography, a resist pattern is created, and wet etching is performed to remove the resist. In this manner, the oxide semiconductor is patterned into an island shape as shown in FIG. 5B, and a semiconductor portion 14 is formed. The oxide semiconductor is constituted by indium (In), gallium (Ga), zinc (Zn), and oxygen (O). The film thickness of the semiconductor portion 14 is between 30 nm and 200 nm, for example. For the oxide conductor, (In, Sn, Zn, O), (In, Si, Zn, O), (In, Al, Zn, O), (Sn, Si, Zn, O), (Sn, Al, Zn, O), (Sn, Ga, Zn, O), (Ga, Si, Zn, O), (Ga, Al, Zn, O), (In, Cu, Zn, O), (Sn, Cu, Zn, O), (Zn, O), (In, O), or the like may also be used, for example.

(4) Forming the Source Wiring Layer 12a

Next, conductive films, Ti and Al, are deposited in that order using a sputtering method over the substrate 20, where the semiconductor portion 14 was formed. Then, in a layer above Al, a MoN conductive film is deposited using a sputtering method. In this manner, a source wiring layer 12a is formed on top of the semiconductor portion 14 by laminating MoN/Al/Ti in that order from the side of the first layer 121. Then, using photolithography, the first layer 121 (MoN) and the second layer 122 (Al) of the source wiring layer 12a are wet etched. Subsequently, the third layer 123 (Ti) of the source wiring layer 12a is dry etched to remove the resist, and a pattern is created. In this manner, as shown in FIG. 5C, the source wiring layer 12a is spaced apart above the semiconductor portion 14, and the channel region 14c, the source electrode 12S, and the drain electrode 12D are formed. For the first layer 121 of the source wiring layer 12a, a metal film made of a metal other than an amphoteric metal is used. Such metals include Mo, Ti, titanium nitride (TiN), and the like, for example. Note that if Ti or TiN is used for the first layer 121, the second layer 122 may be wet etched after the first layer 121 is dry etched, and the third layer 123 may then be dry etched. The film thickness of the first layer 121 is between 10 nm and 100 nm, for example. The film thickness of the second layer 122 is between 100 nm and 400 nm, for example, and the film thickness of the third layer 123 is between 30 nm and 100 nm, for example.

(5) Forming the Protective Layers 22 and 23

Next, using a CVD method, SiO₂ is deposited to form the protective layer 22 over the substrate 20, where the source wiring layer 12a was formed. After the protective layer 22 is deposited, a positive-type light-sensitive resin film is patterned into the protective layer 23 using photolithography. Then, by patterning the protective layer 22 by dry etching, the contact hole H is formed as shown in FIG. 5D. This exposes a surface of the source wiring layer 12a (drain electrode 12D) in the contact hole H. The film thickness of the protective layer 22 is between 100 nm and 300 nm, for example, while the film thickness of the protective layer 23 is between 1 μm and 4 μm, for example. While the protective layer 22 is formed by a SiO₂ single layer film in the present embodiment, a multilayer film of SiNₓ and SiO₂ or a single layer film of SiNₓ may also be used.

(6) Forming the Pixel Electrode 16

Using a sputtering method, ITO (indium tin oxide) is deposited to form the pixel electrode 16 over the substrate 20, where the protective layer 23 was formed. Then, a resist pattern is formed using photolithography, and patterning is performed by wet etching. In this manner, the pixel electrode 16 is formed in the contact hole H so as to overlap a portion of the protective layer 23. In the contact hole H, the pixel electrode 16 and the drain electrode 12D contact each other, and the pixel electrode 16 and the drain electrode 12D are electrically connected. The film thickness of the pixel electrode 16 is between 50 nm and 200 nm, for example. While ITO is used for the pixel electrode 16 in the present embodiment, an oxide thin film such as IZO (indium zinc oxide) may also be used.

In the embodiment described above, the source wiring layer 12a constituted by a multilayer film of MoN/Al/Ti is formed above the semiconductor portion 14. When the source electrode 12S and the drain electrode 12D are formed, the source wiring layer 12a is exposed to the resist stripping solution. However, MoN is formed in the uppermost layer of the source wiring layer 12a in the above embodiment. For this reason, Al is less easily exposed to the stripping solution, and galvanic corrosion between the oxide semiconductor and the source wiring layer 12a is suppressed.

An embodiment of the present invention has been described above, but the above embodiment is a mere example of an implementation of the present invention. The present invention is not limited to the above embodiment, and can be implemented by appropriately modifying the above embodiment without departing from the spirit thereof. Modifications of the present invention are described below.

### Modification Example 1

In the embodiment described above, an example in which the pixel electrode 16 is formed on the side of the active matrix substrate 2 and a common electrode (omitted from diagrams) is formed on the side of the opposite substrate 3 was described. In the present modification, an example in which the pixel electrode 16 and the common electrode are formed on the side of the active matrix substrate 2 will be described.

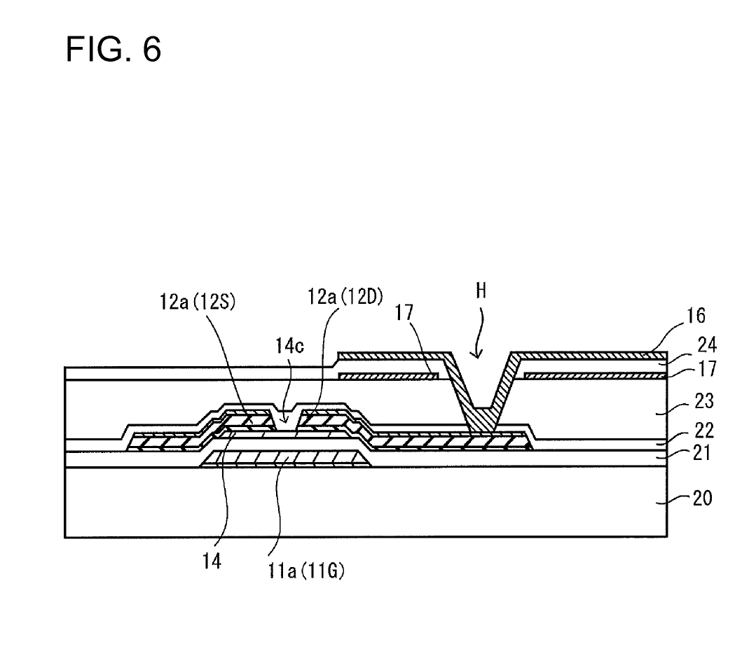

FIG. 6 is a cross-sectional view showing a schematic configuration of an enlarged portion of the semiconductor device according to the present modification. For those elements that are identical to those of the embodiment, reference characters that are identical to those of the embodiment are used in this diagram. In the present modification, as shown in FIG. 6, a common electrode 17 made of a transparent conductive film is formed in a layer above a protective layer 23 in the vicinity of a contact hole H. In a layer above the common electrode 17, an interlayer insulating layer 24 made of SiNₓ is formed. Then, a pixel electrode 16 made of a transparent conductive film is formed in the contact hole H so as to overlap a portion of the interlayer insulating film 24. In the present modification, liquid crystal is driven by the pixel electrode 16 and the common electrode 17 formed on the active matrix substrate 2 using a horizontal electric field method called IPS (In Plane Switching) or FFS (fringe field switching).

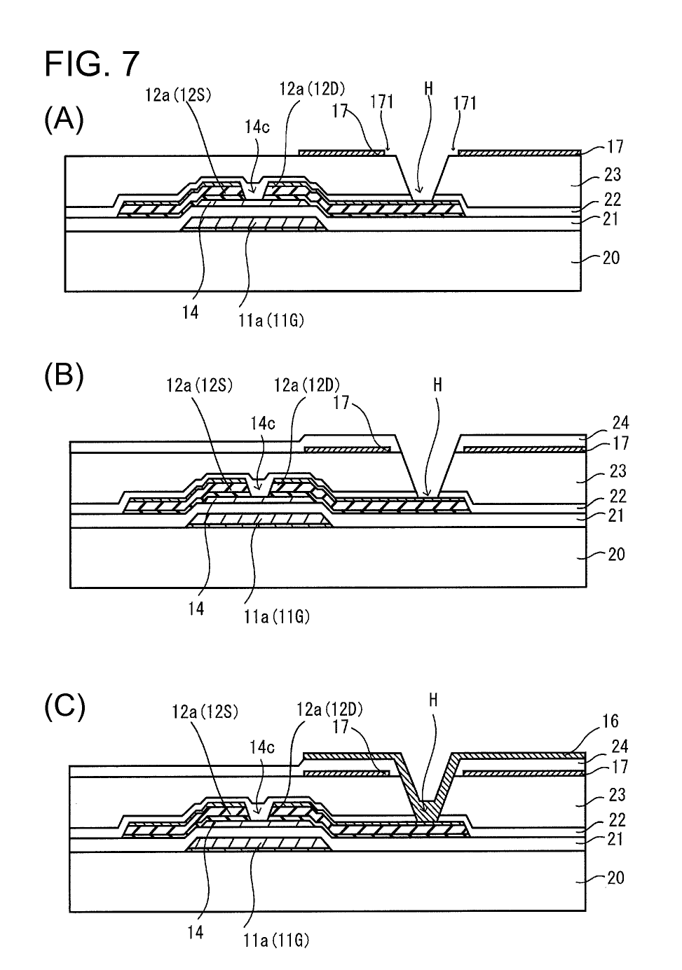

The steps of manufacturing the semiconductor device according to the present modification will be explained below using FIGS. 7A to 7C. FIGS. 7A to 7C are diagrams showing the steps of manufacturing the semiconductor device shown in FIG. 6. Here, the steps up to the forming of the protective layer 23 are identical to the steps of manufacturing (1) to (5) described in the embodiment, and will therefore be omitted.

(6′) Forming the Common Electrode 17

After the contact hole H is formed in the protective layer 22 and the protective layer 23, a common electrode 17 made of ITO is deposited in a layer above the protective layer 23 using a sputtering method. Then, a resist pattern is formed using photolithography, and the resist is stripped by wet etching to create a pattern. In this manner, an opening 171 of the common electrode 17 is formed in the vicinity of the contact hole H as shown in FIG. 7A. As a result, the common electrode 17 is formed on the outside of the opening 171. The film thickness of the common electrode 17 is between 50 nm and 200 nm, for example. A thin oxide film such as IZO (indium zinc oxide) may also be used for the common electrode 17.

(7′) Forming the Interlayer Insulating Layer 24

Next, SiNₓ is deposited to form an interlayer insulating layer 24 using a CVD method over the substrate 20, where the common electrode 17 was formed. Then, a resist pattern is formed using photolithography, and the resist is stripped by dry etching to create a pattern. In this manner, an interlayer insulating layer 24 is formed so as to cover the common electrode 17, as shown in FIG. 7B. The film thickness of the interlayer insulating layer 24 is between 100 nm and 300 nm, for example. An inorganic insulation film such as SiO₂ or a multilayer film of SiNₓ and SiO₂ may also be used for the interlayer insulating film 24.

(8′) Forming the Pixel Electrode 16

ITO is deposited to form the pixel electrode 16 over the substrate 20, where the interlayer insulating layer 24 was formed. Then, a resist pattern is formed using photolithography, and the resist is stripped by wet etching to create a pattern. As shown in FIG. 7C, the pixel electrode 16 is formed in the contact hole H so as to overlap the common electrode 17, with the interlayer insulating layer 24 therebetween. In this manner, the pixel electrode 16 is electrically connected to a source wiring layer 12a in the contact hole H. The film thickness of the pixel electrode 16 is between 50 nm and 200 nm, for example. A thin oxide film such as IZO (indium zinc oxide) may also be used as the pixel electrode 16.

In the present modification, too, a metal is formed in the uppermost layer of the source wiring layer 12a so as to suppress galvanic corrosion between the source wiring layer 12a and the semiconductor portion 14, in a manner similar to the embodiment. For this reason, Al of the source wiring layer 12a becomes less easily exposed to the resist stripping solution when a channel region 14c is formed, and galvanic corrosion between the source wiring layer 12a and the semiconductor portion 14 is suppressed.

### Modification Example 2

In the embodiment described above, an example in which the source wiring layer 12a has a three-layer structure constituted by the first layer 121, the second layer 122, and the third layer 123 was described. However, a two-layer structure constituted by a MoN first layer 121 and an Al second layer 122 is also acceptable. In this case, a semiconductor portion 14 can be configured using an oxide semiconductor that has a resistance to wet etching performed on the first layer 121 and the second layer 122 when the source wiring layer 12a is formed.

### Modification Example 3

In the embodiment described above, an example in which the display panel 1 is a liquid crystal panel was described. However, a display panel using organic EL (Electro-Luminescence) or the like may also be used.

### INDUSTRIAL APPLICABILITY

Industrial applications of the present invention include display devices incorporating a liquid crystal display, an organic EL display, or the like.

1. A semiconductor device, comprising:
a gate electrode formed on a substrate;
a gate insulating film covering said gate electrode;
a semiconductor layer made of an oxide semiconductor formed so as to overlap said gate electrode, said gate insulating film being interposed therebetween;
a wiring layer formed on said gate insulating film by spacing apart a conductive film on said semiconductor layer, said conductive film of the wiring layer including a first conductive layer made of aluminum and a second conductive layer stacked on said first conductive layer;
an insulating layer formed in a layer above said wiring layer; and
a pixel electrode electrically connected to said source wiring layer via a contact hole provided in said insulating layer,
wherein said second conductive layer in the conductive film of said source wiring layer is a metal film made of a metal other than an amphoteric metal.

2. The semiconductor device according to claim 1,
wherein said wiring layer further includes a bottom conductive layer under said first conductive layer, and
wherein said bottom conductive layer is a metal film made of titanium or a metal compound including titanium that is in contact with said semiconductor layer.

3. The semiconductor device according to claim 1, wherein said second conductive layer of the wiring layer is a metal film made of a metal compound including molybdenum.

4. The semiconductor device according to claim 1, wherein said second conductive layer of the wiring layer is a metal film made of a metal compound including titanium.

5. The semiconductor device according to claim 1, wherein the oxide semiconductor comprises indium, gallium, zinc, and oxygen.

6. A display panel, comprising:
an active matrix substrate having the semiconductor device according to claim 1;
an opposite substrate having a common electrode and color filters; and
a liquid crystal layer sandwiched between said active matrix substrate and said opposite substrate.

7. A display panel, comprising:
an active matrix substrate having the semiconductor device according to claim 1 and a common electrode;
an opposite substrate having color filters; and
a liquid crystal layer sandwiched between said active matrix substrate and said opposite substrate.

8. A method of manufacturing a semiconductor device equipped with thin film transistors, comprising:
(a) forming a gate layer having a gate line and a gate electrode;
(b) forming a gate insulating film so as to cover said gate layer;
(c) forming a semiconductor layer made of an oxide semiconductor so as to overlap said gate electrode, said gate insulating film being interposed therebetween;
(d) forming a source electrode and a drain electrode by forming a wiring layer that includes: a first conductive layer made of aluminum on said gate insulating film and on said semiconductor layer; and a second conductive layer on said first conductive layer, such that said wiring layer has a gap therein on said semiconductor layer;
(e) forming a first protective layer covering said wiring layer and a second protective layer covering said first protective layer;
(f) forming a contact hole that exposes said drain electrode by etching said first protective layer and said second protective layer; and
(g) forming a pixel electrode so as to contact said drain electrode in said contact hole,
wherein said second conductive layer is a metal film made of a metal other than an amphoteric metal.

9. The method of manufacturing according to claim 8, wherein said wiring layer further includes a bottom conductive layer under the first conductive layer, the bottom conductive layer being made of titanium or a metal compound including titanium that is in contact with said semiconductor layer.

10. The method of manufacturing according to claim 8, wherein the oxide semiconductor comprises indium, gallium, zinc, and oxygen.
